(19) United States
(12) Patent Application Publication
(10) Pub. No.: US 2002/0047111 A1
(43) Pub. Date: Apr. 25, 2002

(54) Semiconductor device having a ferroelectric capacitor with tensile stress properties

(76) Inventor: Yuji Judai, Uji-shi (JP)

Correspondence Address: Ratner & Prestia, P.O. Box 980, Valley Forge, PA, 19482, US

(21) Appl. No.: 09/990,474

(22) Filed: Nov. 21, 2001

Related U.S. Application Data
(62) Division of application No. 09/177,038, filed on Oct. 22, 1998, now abandoned.

(30) Foreign Application Priority Data
Oct. 24, 1997 (JP) HEI 9-293,046

(51) Int. Cl. H01L 47/00

(52) U.S. Cl. 257/1

(57) ABSTRACT

A semiconductor device has

a circuit board,

a ferroelectric capacitor arranged on said circuit board having a ferroelectric thin film and top and bottom electrodes which are formed so as to hold said ferroelectric thin film,

an insulating film formed on said circuit board so as to cover said ferroelectric capacitor,

a metallic wiring film formed on said insulating film so as to connect with either of said top and bottom electrodes, and

a surface protective film formed so as to cover said insulating film and said metallic wiring film, wherein

a synthetic stress working in a surface direction of the ferroelectric thin film of said ferroelectric capacitor is an extensional stress.

### BACKGROUND OF THE INVENTION

1. Field of the Invention

The present invention relates to a semiconductor device, particularly to a nonvolatile memory provided with a ferroelectric capacitor and its fabrication method.

2. Related Art of the Invention

Recently, an attempt of integrating a capacitor using a ferroelectric thin film in a semiconductor device to obtain a new performance has been positively performed. This is because a ferroelectric thin film has a dielectric constant one place or more higher than that of a conventional silicon oxide film or silicon nitride film and is advantageous for high integration and refining, and moreover the ferroelectric thin film holds electric charges even for a voltage of 0 depending on the material and makes it possible to easily realize a nonvolatile memory.

FIG. 3 shows a sectional view of a semiconductor device in which a ferroelectric capacitor is integrated in accordance with the prior art. In FIG. 3, the ferroelectric capacitor is formed with a top electrode 13a, a bottom electrode 13b, and a ferroelectric thin film 13c on a circuit board 11 comprising a conventional CMOS through an insulting film 12. An insulating film 14 is formed on the ferroelectric capacitor and the CMOS circuit board is connected by wiring films 15a and 15b through a connection hole 14a. Moreover, a surface protective film 16 is formed on the wiring films 15a and 15b to protect each element from moisture.

In this case, the insulating film 14 is formed through the plasma-excitation CVD method and the wiring films 15a and 15b are formed through the sputtering method. Moreover, the surface protective film 16 is formed through the plasma-excitation CVD method.

However, the above conventional structure has a disadvantage that characteristics of the ferroelectric thin film are deteriorated and thereby, the performance cannot be completely achieved.

A ferroelectric thin film is a material sensitive for a stress and its characteristics are greatly fluctuated due to the influence of stresses of various films formed on an upper part of a ferroelectric capacitor. In general, when an extension-directional stress is applied to the film, such characteristics as leak current and residual dielectric polarization are improved. However, when a compression-directional stress is applied to the film, its characteristics are deteriorated.

Moreover, in the case of the above semiconductor device and its fabrication method according to the prior art, each thin film formed on a ferroelectric capacitor has a compressive stress to the ferroelectric capacitor. Arrows in FIG. 3 show stress directions of thin films. Each thin film has a compression-directional stress, that is, works so as to deteriorate characteristics of a ferroelectric thin film. Therefore, as a result, a semiconductor device in which a ferroelectric thin film is integrated cannot completely show its performances.

FIG. 4 shows the polarization characteristic of a ferroelectric capacitor integrated in a semiconductor device according to the above prior art. Because of the above-described reason, the polarization characteristic originally owned by a conventional ferroelectric thin film is not shown and it is found that a polarization value Pr (also referred to as residual dielectric polarization) for a voltage of 0 has a small value.

### SUMMARY OF THE INVENTION

The present invention is made to solve the above conventional problems and its object is to provide a semiconductor device capable of integrating a ferroelectric thin film free from characteristic deterioration and its fabrication method.

A semiconductor device of the present invention comprises

a circuit board,

a ferroelectric capacitor arranged on said circuit board having a ferroelectric thin film and top and bottom electrodes which are formed so as to hold said ferroelectric thin film,

an insulating film formed on said circuit board so as to cover said ferroelectric capacitor,

a metallic wiring film formed on said insulating film so as to connect with either of said top and bottom electrodes, and

a surface protective film formed so as to cover said insulating film and said metallic wiring film, wherein

a synthetic stress working in a surface direction of the ferroelectric thin film of said ferroelectric capacitor is an extensional stress.

The semiconductor device according to claim 1 of the present invention, is such that

said insulting film, metallic wiring film, and surface protective film provide the surface-directional extensional stress of the ferroelectric thin film of said ferroelectric capacitor.

The semiconductor device according to claim 1 or 2 of the present invention is such that

said metallic wiring film is constituted with two layers which are different kinds of metal.

A semiconductor device fabrication method for fabricating the semiconductor device of the present invention comprises the step of:

forming said insulating film on said ferroelectric capacitor by the TEOS-CVD method utilizing TEOS activated by O₃.

A semiconductor device fabrication method for fabricating the semiconductor device of the present invention is such that

said metallic wiring film is constituted with two layers where a bottom layer thereof is made of TiN, and

such step of heat-treating of said formed TiN layer in a temperature range of 200 to 650° C. after forming said TiN layer is included.

A semiconductor device fabrication method for fabricating the semiconductor device of the present invention is such that

said metallic wiring film is constituted with two layers where a top layer thereof is made of Al, and

such step of forming said Al layer through the sputtering method while heating said circuit board in a temperature range of 100 to 400° C. is included.

A semiconductor device fabrication method for fabricating the semiconductor device of the present invention is such that

said surface protective film is made of SiN, and

such step of forming said surface protective film by depositing SiN through the plasma-excitation CVD method having an RF power of 300 W or less is included.

The above semiconductor device of the present invention can show a superior performance that the ferroelectric-pair thin film of the ferroelectric capacitor is not deteriorated.

Moreover, the semiconductor device fabrication method of the present invention can realize a semiconductor device having the above superior performance.

### BRIEF DESCRIPTION OF THE DRAWINGS

FIG. 1 is a sectional view of the ferroelectric capacitor of the semiconductor device of an embodiment of the present invention;

FIG. 2 is an illustration showing the polarization characteristic of the ferroelectric capacitor integrated in the semiconductor device of an embodiment of the present invention;

FIG. 3 is a sectional view of the ferroelectric capacitor of a conventional semiconductor device; and

FIG. 4 is an illustration showing the polarization characteristic of the ferroelectric capacitor integrated in a conventional semiconductor device.

### PREFERRED EMBODIMENTS

Embodiments of the present invention are described below by referring to the accompanying drawings.

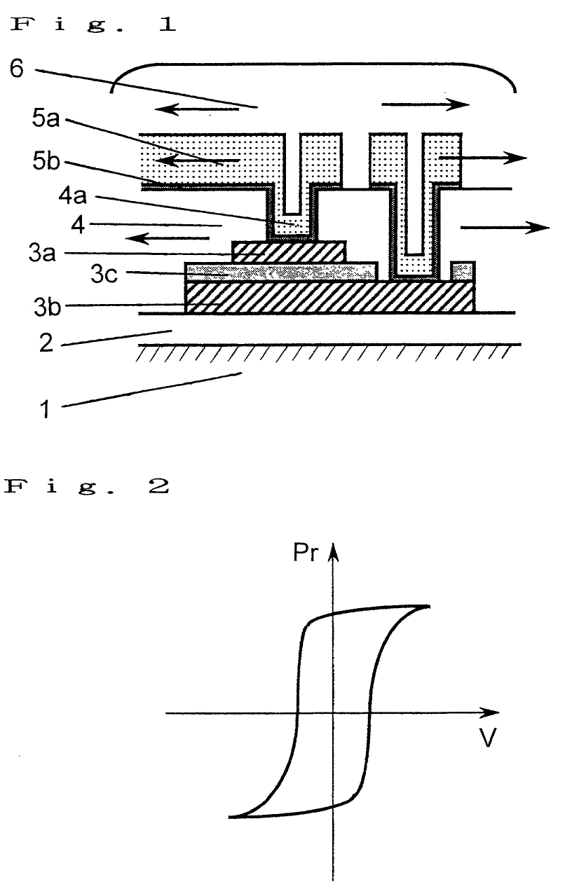

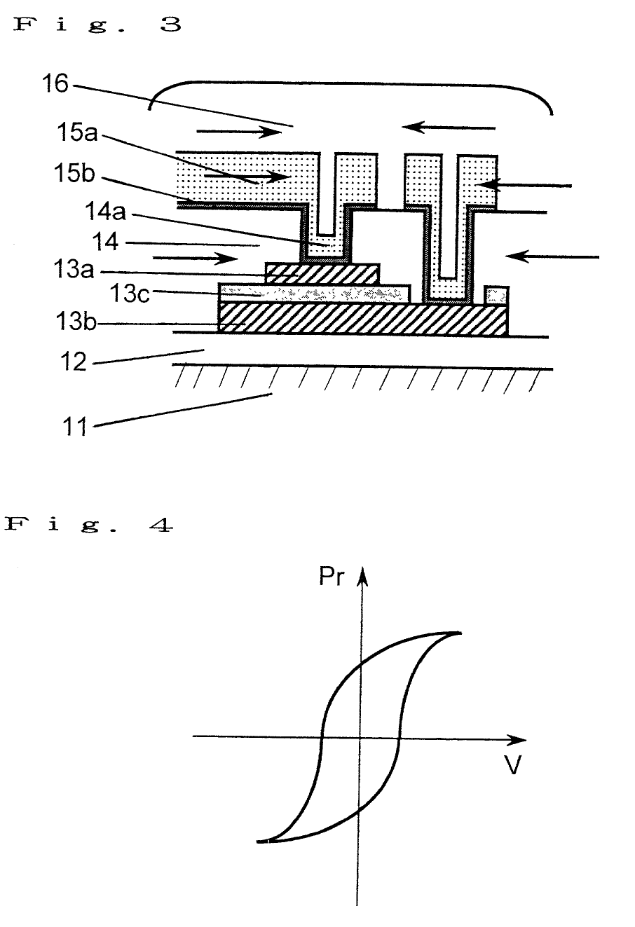

FIG. 1 shows a sectional view of the ferroelectric capacitor of the semiconductor device of an embodiment of the present invention. In FIG. 1, the ferroelectric capacitor is formed with a top electrode 3a, a bottom electrode 3b, and a ferroelectric thin film 3c on a circuit board 1 comprised of conventional CMOS through an insulating film 2. An insulating film 4 is formed on the ferroelectric capacitor and a CMOS circuit board is connected to wiring films 5a and 5b through a connection hole 4a in the film 4. Moreover, a surface protective film 6 is formed on the wiring films 5a and 5b to protect each element from moisture.

The semiconductor device of this embodiment is characterized in that the sum of stresses of thin films deposited on the ferroelectric capacitor is an extensional stress. In FIG. 1, arrows show stress directions of thin films. Because the sum of stresses of thin films formed on the ferroelectric capacitor has an extensional direction, an extensional stress is applied to the ferroeleotric capacitor to prevent ferroelectric characteristics from deteriorating.

Moreover, the semiconductor device of this embodiment is characterized in that every thin film deposited on the ferroelectric capacitor applies an extension-directional stress to the ferroelectric capacitor. Because every thin film deposited on the ferroelectric capacitor has an extension-directional stress, an extensional stress is applied to the ferroelectric capacitor to prevent ferroelectric characteristic from deteriorating.

FIG. 2 shows the polarization characteristic of a ferroelectric capacitor integrated in the semiconductor device of the above embodiment. The polarization characteristic originally owned by a ferroelectric thin film is shown and a residual dielectric polarization Pr for a voltage of 0 also shows a large-enough value. A semiconductor device in which the ferroelectric capacitor is integrated makes it possible to completely achieve the purposed performances.

Then, a fabrication method of the semiconductor device of this embodiment is described below.

In FIG. 1, an insulating film 4 is formed on the ferroelectric capacitor through the TEOS-CVD method using TEOS activated by O₃ (ozone). An insulating film formed through plasma excitation having been used in a prior art so far has a compression-directional stress independently of conditions. Moreover, an insulating film formed through the TEOS-CVD method using TEOS activated by O₃ has an extension-directional stress and thereby, prevents characteristics of the ferroelectric capacitor from deteriorating.

Then, a TiN film is formed as a bottom-layer film 5b of a wiring film through the sputtering method to heat-treat the TiN film in a temperature range of 200 to 650° C. Though the TiN film immediately after sputtering has a compression-directional stress, the stress direction changes to an extensional direction by heat-treating the film in the temperature range of 200 to 650° C. That is, the film has a stress in a direction in which ferroelectric capacitor characteristics are not deteriorated.

Moreover, an Al film is formed as a top-layer film 5a of a wiring film through the sputtering method while heating a substrate at a high temperature of 100 to 400° C. The Al film is generally formed at room temperature of an approx. 25° C. without controlling temperature. In this case, a deposited film has a compression-directional stress. However, when heating the substrate at a high temperature of 100° C. or higher, a deposited Al film has an extension-directional stress. Because the Al film is melted at a temperature of 400° C. or higher, it cannot be used as a wiring film. Therefore, by depositing an Al film in a temperature range of 100 to 400° C. through the sputtering method, it is possible for the Al film to have a stress in a direction in which ferroelectric capacitor characteristics are not deteriorated.

Furthermore, an SiN (silicon nitride) film is deposited as a surface protective film 6 through the plasma-excitation CVD method having a RF power of 300 W or less. The stress direction of the SiN film according to plasma excitation depends on RF power. An SiN film formed by a generally-used RF power of approx. 400 W has a compression-directional stress. However, when decreasing the RF power up to 300 W, the stress becomes almost 0. The stress direction of an SiN film formed at 300 W or less reverses to an extensional direction. That is, by forming an SiN film at an RF power of 300 W or less, it is possible for the film to have a stress in a direction in which ferroelectric-capacitor characteristics are not deteriorated.

Furthermore, in the above emobdiment every insulting film, metallic wiring film, and surface protective film are described as providing a surface-directional extensional stress to the the ferroelectric thin film. However, it is possible to prevent a ferroelectric-capacitor characteristics from deteriorating compared to the case of a conventional example as long as a synthetic stress working in the surface direction of the ferroelectric thin film of a ferroelectric capacitor is an extensional stress.

Furthermore, it is described that a metallic wiring film of the present invention is constituted with top and bottom separate metallic layers in the case of this embodiment and the bottom layer is made of TiN and the top layer is made of Al. However, it is also possible to use a metallic film of only one layer. In short, as long as a synthetic stress working in the surface direction of the ferroelectric thin film of a ferroelectric capacitor is an extensional stress, the material of a metallic wiring film is not restricted.

Furthermore, for a semiconductor device of the present invention, it is described that an insulating film of the present invention is formed through the TEOS-CVD method using TEOS activated by O₃, the bottom layer of a metallic wiring film of the present invention is made of a TiN layer heat-treated in a temperature range of 200 to 650° C., the top layer of the metallic wiring film of the present invention is made of an Al layer formed through the sputtering method while heating a circuit board in a temperature range of 100 to 400° C., and a surface protective film of the present invention is formed by depositing an SiN through the plasma-excitation CVD method having an RF power of 300 W or less. However, in short, as long as a synthetic stress working in the surface direction of the ferroelectric thin film of a ferroelectric capacitor is an extensional stress, the material and forming method of each film are not restricted.

As described above, the present invention makes it possible to provide a semiconductor device capable of integrating a ferroelectric thin film free from characteristic deterioration and its fabrication method.

What is claimed is:

1. A semiconductor device comprising
a circuit board,
a ferroelectric capacitor arranged on said circuit board having a ferroelectric thin film and top and bottom electrodes which are formed so as to hold said ferroelectric thin film,
an insulating film formed on said circuit board so as to cover said ferroelectric capacitor,
a metallic wiring film formed on said insulating film so as to connect with either of said top and bottom electrodes, and
a surface protective film formed so as to cover said insulating film and said metallic wiring film, wherein
a synthetic stress working in a surface direction of the ferroelectric thin film of said ferroelectric capacitor is an extensional stress.

2. The semiconductor device according to claim 1, wherein
said insulting film, metallic wiring film, and surface protective film provide the surface-directional extensional stress of the ferroelectric thin film of said ferroelectric capacitor.

3. The semiconductor device according to claim 1 or 2, wherein
said metallic wiring film is constituted with two layers which are different kinds of metal.

4. A semiconductor device fabrication method for fabricating the semiconductor device according to claim 1; comprising the step of:
forming said insulating film on said ferroelectric capacitor by the TEOS-CVD method utilizing TEOS activated by O₃.

5. A semiconductor device fabrication method for fabricating the semiconductor device according to claim 2 comprising the step of:
forming said insulating film on said ferroelectric capacitor by the TEOS-CVD method utilizing TEOS activated by O₃.

6. A semiconductor device fabrication method for fabricating the semiconductor device according to claim 3 comprising the step of:
forming said insulating film on said ferroelectric capacitor by the TEOS-CVD method utilizing TEOS activated by O₃.

7. A semiconductor device fabrication method for fabricating the semiconductor device according to claim 1, wherein
said metallic wiring film is constituted with two layers where a bottom layer thereof is made of TiN, and
such step of heat-treating of said formed TiN layer in a temperature range of 200 to 650° C. after forming said TiN layer is included.

8. A semiconductor device fabrication method for fabricating the semiconductor device according to claim 2, wherein
said metallic wiring film is constituted with two layers where a bottom layer thereof is made of TiN, and
such step of heat-treating of said formed TiN layer in a temperature range of 200 to 650° C. after forming said TiN layer is included.

9. A semiconductor device fabrication method for fabricating the semiconductor device according to claim 3, wherein
said metallic wiring film is constituted with two layers where a bottom layer thereof is made of TiN, and
such step of heat-treating of said formed TiN layer in a temperature range of 200 to 650° C. after forming said TiN layer is included.

10. A semiconductor device fabrication method for fabricating the semiconductor device according to claim 1, wherein
said metallic wiring film is constituted with two layers where a top layer thereof is made of Al, and
such step of forming said Al layer through the sputtering method while heating said circuit board in a temperature range of 100 to 400° C. is included.

11. A semiconductor device fabrication method for fabricating the semiconductor device according to claim 2, wherein
said metallic wiring film is constituted with two layers where a top layer thereof is made of Al, and
such step of forming said Al layer through the sputtering method while heating said circuit board in a temperature range of 100 to 400° C. is included.

12. A semiconductor device fabrication method for fabricating the semiconductor device according to claim 3, wherein
said metallic wiring film is constituted with two layers where a top layer thereof is made of Al, and
such step of forming said Al layer through the sputtering method while heating said circuit board in a temperature range of 100 to 400° C. is included.

13. A semiconductor device fabrication method for fabricating the semiconductor device according to claim 1, wherein
said surface protective film is made of SiN, and
such step of forming said surface protective film by depositing SiN through the plasma-excitation CVD method having an RF power of 300 W or less is included.

14. A semiconductor device fabrication method for fabricating the semiconductor device according to claim 2, wherein
said surface protective film is made of SiN, and
such step of forming said surface protective film by depositing SiN through the plasma-excitation CVD method having an RF power of 300 W or less is included.

15. A semiconductor device fabrication method for fabricating the semiconductor device according to claim 3, wherein
said surface protective film is made of SiN, and
such step of forming said surface protective film by depositing SiN through the plasma-excitation CVD method having an RF power of 300 W or less is included.
